(19) United States
(12) Patent Application Publication
(10) Pub. No.: US 2013/0316470 A1
(43) Pub. Date: Nov. 28, 2013

(54) METHOD WHICH CAN FORM CONTACT HOLES IN WAFER OF SEMICONDUCTOR

(71) Applicant: SHANGHAI HUALI MICROELECTRONICS CORPORATION, Shanghai (CN)

(72) Inventor: Jun ZHOU, Shanghai (CN)

(73) Assignee: SHANGHAI HUALI MICROELECTRONICS CORPORATION, Shanghai (CN)

(21) Appl. No.: 13/707,485

(22) Filed: Dec. 6, 2012

(30) Foreign Application Priority Data
May 22, 2012 (CN) 201210158835.0

(51) Int. Cl. H01L 21/66

(52) U.S. Cl. CPC H01L 22/26
USPC 438/8

(57) ABSTRACT

The present invention relates to the field of semiconductor integrated circuits, and particularly relates to a method which can form a contact hole in a wafer of semiconductor material. The invention has proposed a method which can form a contact hole in a wafer of semiconductor: measuring and comparing a Critical Dimension (CD) of a position corresponding to the contact hole in the hard mask with the CD required in the technology, and then, based on the measurement, adjusting the CD of the position corresponding to the contact hole in the hard mask, by conformal deposition or etching technology, to fit a requirement of the technology; the method can reduce process costs while improving production capacity.

The present application claims priority under the Paris Convention to Chinese application number CN 201210158835.0, filed on May 22, 2012, the disclosure of which is herewith incorporated by reference in its entirety.

### FIELD OF THE INVENTION

The present invention relates to semiconductor integrated circuit technology; in particular, it relates to a method which can form contact holes in a wafer of a substrate such as a semiconductor substrate.

### BACKGROUND OF THE INVENTION

In current semiconductor technology, an integrated circuit (IC) usually includes millions of electronic devices. With the development of the technology and the ever-increasing application demands, IC technology is trending towards micronized, multi-layered, planarized and thinned devices; and there are commonly integrated ten-thousands or even millions of transistors on a silicon die which is on the order of several millimetres square; especially in the super-large-scale IC.

The primary device of the super-large-scale IC is metal oxide semiconductor field effect transistor (MOS transistor). Since MOS transistors were first invented and applied, their dimensions have been shrinking, and for now the Critical Dimension of which has been in the range of 22 nm. In the above dimension, there appears varieties of practical and fundamental limits, and technical challenges, such as 3D Through Silicon Via (TSV), which uses the method that integrates wafer stacks, via vertical breakover, to achieve electrical interconnection among the chips. We can use this technology to let the method which integrates the components enter into the new stage of the area-array-like Interconnects which uses perforation channels; and the above technology can make different chips or wafers stack together to achieve faster speed, less noise and better performance, and these can make electrical products achieve innovative functions.

With further shrinking of the dimensions of devices, it is a big challenge for requirement of manufacturing technology. In the preparation of MOS transistor devices and circuits, with shrinking of the dimensions of devices, a problem impacts the current semiconductor preparation technology; specifically how to form smaller contact holes on the substrate to provide connection among each circuit and each layer of circuits.

In the routine technology, people usually use ultraviolet photo exposure machine and transfer patterns to the hard mask via lithographic technology, and then form a contact hole with a particular inner diameter via etching the hard mask. But with shrinking of the dimension of devices, the regular ultraviolet photo exposure machine can not satisfy requirement of the hard mask with contact holes which have a minimum diameter, and it becomes much more difficult to get contact holes with required inner diameter by photo etching and further etching; and because the extreme ultraviolet lithographic (EUV) exposure machine which satisfies the technology requirement is extremely expensive, it greatly increases the input of the semiconductor preparation technology and the cost of manufacturing.

Although a new hard mask formed by atomic layer deposition (ALD) technology can also satisfy the technology requirement, the production capacity of ALD is relatively low while the cost is extremely high; and ALD is a very new technology, it costs much more to purchase new machines for implementation.

### SUMMARY OF THE INVENTION

The present invention discloses a method which can form contact holes in a wafer of semiconductor, wherein the method includes the following steps:
Step S1: Preparing a patterned hard mask corresponding to contact holes on the upper surface of a silicon substrate, and then measuring the critical dimension of the patterned hard mask corresponding to contact holes; if said critical dimension is larger than the critical dimension required in the technology, then go to step S2; if said critical dimension is smaller than the critical dimension required in the technology, then go to step S4; if said critical dimension is equal to the critical dimension required in the technology, then go to step S5;
Step S2: Depositing a further hard mask film to conformally cover an underlying patterned hard mask;
Step S3: Measuring the critical dimension of the hard mask of which the position is corresponding to contact holes; if said critical dimension is larger than the critical dimension required in the technology, then return to step S2; if said critical dimension is smaller than the critical dimension required in the technology, then go to step S4; if said critical dimension is equal to the critical dimension required in the technology, then go to step S5;
Step S4: Removing redundant hard mask by etching technology, so as to let the critical dimension of the contact hole be equal to the critical dimension required in the technology;
Step S5: Etching the silicon substrate using the hard mask, which has a critical dimension fitting the requirement in the technology, as a mask; after forming a contact hole, removing the rest of the hard mask;
The above method, wherein depositing the hard mask film in step S2 is prepared by chemical deposition technology.
The above method, including executing the etching in step S4 by SiCoNi etching technology.
The above method, including etching the contact holes of step S5 by dry etching technology.
The above method, including removing the rest of the hard mask in step S5 by wet etching technology.
The above method, wherein the diameter of the formed contact holes ranges from 1 nm to 100 nm.
The above method, wherein the depth of the formed contact holes ranges from 1 nm to 1000 nm.

In conclusion, based on the above technical solution, the invention has proposed a method which can form contact holes in wafer of semiconductor: measuring the critical dimension of the position on the hard mask corresponding to contact holes and comparing said critical dimension with the critical dimension required in the technology, and then adjusting said critical dimension by conformally depositing the hard mask or etching technology based on the above measurement to the requirement in the technology, which can reduce technology cost while improving production capacity.

### BRIEF DESCRIPTION OF THE DRAWINGS

FIG. 1 is a flow diagram for the method which can form contact holes in wafer of semiconductor in this invention; and

FIG. 2-6 are flow structure diagrams for the method which can form contact holes in wafer of semiconductor in this invention.

### DETAILED DESCRIPTION OF THE PREFERRED EMBODIMENT

The present invention will be further elaborated in the following with figures:

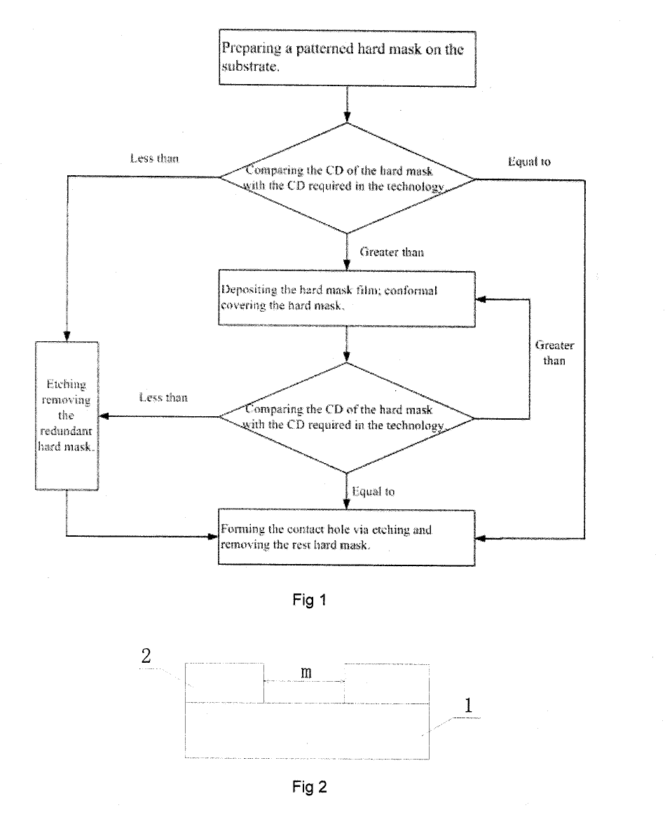

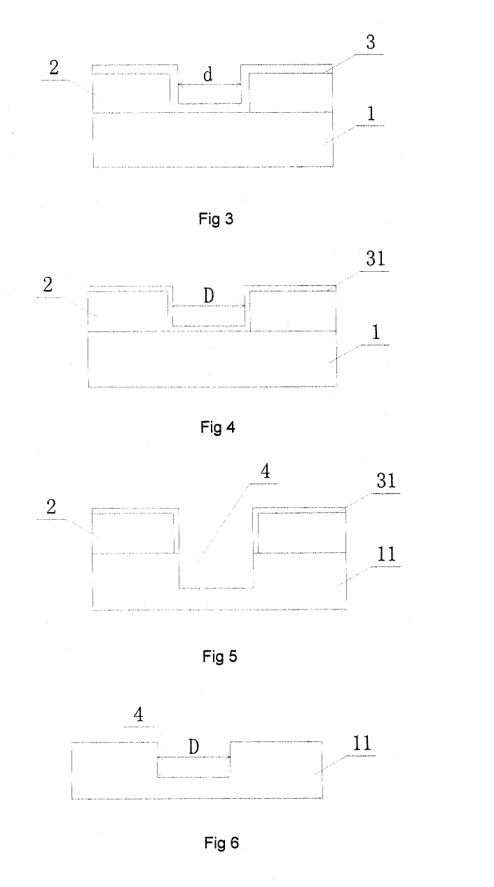

FIG. 1 is a flow diagram for the method which can form contact holes in wafer of semiconductor in this invention; and FIGS. 2-6 are flow structure diagrams for the method which can form contact holes in wafer of semiconductor in this invention.

As shown in FIG. 1-6, a method which can form contact holes in wafer of semiconductor in MOS semiconductor manufacturing technology includes the following steps:

Firstly, as shown in FIG. 2, preparing the patterned hard mask 2 of which the position is corresponding to contact holes, the hard mask 2 having the openings for forming the contact holes in substrate 1 by etching process, and the patterned hard mask 2 covers the upper surface of the silicon substrate 1, and then measuring the value m of the critical dimension(CD) of the position (for example, CD of openings formed in hard mask 2) corresponding to the contact holes on said patterned hard mask 2; comparing m with the value D of the CD required (the expectant CD value) in the technology: if m=D, then etching the silicon substrate 1 using said patterned hard mask 2 as a etching mask by dry etching technology, to form contact holes of which the diameter ranges from 1 nm to 100 nm and the depth ranges from 1 nm to 1000 nm, and then removing the patterned hard mask 2 by wet etching technology. If m<D, then removing the rest hard mask (the undesired portion) by SiCoNi etching technology to make the fact CD of the patterned hard mask fit the requirement (make the fact CD meet the D) in the technology. In fact the removed portion of hard mask 2 is the undesired portion, for example, at least a portion of hard mask 2 surrounding the openings is removed by a etching process for increasing dimension of openings until m equal to D. After that, forming the contact holes and subsequently removing the hard mask.

Secondly, if m>D, as shown in FIG. 3, depositing another hard mask film 3 by chemical vapor deposition(CVD) technology to cover the upper surface of the patterned hard mask 2, also the bottom and the side walls of the openings which formed in the patterned hard mask 2 are covered by film 3; and then measuring the critical value d of the hard mask 2 which covered by the hard mask film 3, for example, measuring the fact CD value(d) for openings while the sidewall of openings is covered by the hard mask film 3. If d>D, then repeating the step of depositing the hard mask film 3 until said critical value d is not less than D; if d=D, then making the hard mask 2 and the hard mask film 3 as a mask for etching silicon substrate 1 to form contact holes, and then removing the hard mask 2 and the rest hard mask film 3.

Thirdly, if d<D, as shown in FIG. 4, removing the redundant hard mask film 3 (the undesired portion) by SiCoNi etching technology, the removed portion of hard mask film 3 is the undesired portion, for example, removing a thin layer from top surface of hard mask film 3 by said etching process for thinning film until d equal to D. In other words, at least a thin layer of hard mask film 3 covered the sidewall of the openings is removed by a etching process for increasing dimension of openings until d equal to D. Instead of plasma etch or HF wet etching, in this dry etching process(also is a pre-cleaning process before the substrate is transferred to Ni/Co deposition Chamber) the said thin layer of the hard mask film 3 is removed, after finish removing the hard mask 2 & the rest hard mask film 31, the substrate is transferred to the Ni/Co deposition Chamber with a vacuum environment. Making the CD of the rest hard mask film 31 and the patterned hard mask 2 fit the requirement (that is making the fact CD value meet the D), and then using the rest hard mask film 31 and hard mask 2 as a etching mask to implement etching for forming contact holes in the substrate, for better understanding the contact holes 4 formed in the rest silicon substrate 11 as shown in FIG. 5. Finally, as shown in FIG. 6, removing the rest hard mask film 31 and the hard mask 2 by wet etching technology, and then forming the contact hole 4 with the CD value equal to D.

The above contact holes, wherein the diameter all ranges from 1 nm to 100 nm, the depth all ranges from 1 nm to 1000 nm, and the above contact holes all removes the rest hard mask by wet etching technology to form the final contact hole structure.

In conclusion, based on the above technical solution, the invention has proposed a method which can form contact holes in wafer of semiconductor: measuring and comparing the CD of the position which corresponding to the contact holes in the hard mask with the CD required in the technology, and then adjusting the CD of the position which corresponding to the contact holes in the hard mask based on the measurement by conformal deposition or etching technology, to fit the requirement in the technology; the method can reduce process costs while improving production capacity. Although having given a typical embodiment of a particular structure of the specific implementation way above with description and the figures, we can make other changes based on the spirit of this invention. Though preferred embodiments are proposed above, these contents are not the limitation of this invention.

It would be obvious for one skilled in the art to make varieties of changes and modifications after reading the above descriptions. Hence, the Claims attached should be regarded as all the changes and modifications which cover the real intention and the range of this invention. Any and all equivalent contents and ranges in the range of the Claims should be regarded belonging to the intention and the range of this invention.

Further, while the invention has been described in detail in connection with the presently preferred embodiments, it should be readily understood that the invention is not limited to such disclosed embodiments. Rather, the invention can be modified to incorporate any number of variations, alterations, substitutions, or equivalent arrangements not heretofore described, but which are commensurate with the spirit and scope of the invention. Accordingly, the invention is not to be seen as limited by the foregoing description, but is only limited by the scope of the appended claims.

1. A method for forming contact holes in a substrate, wherein the method comprises the steps of:
Step S1: Preparing a bottom patterned hard mask corresponding to contact holes on the upper surface of a sillicon substrate, and then measuring the critical dimension of the patterned hard mask corresponding to contact holes; if said critical dimension is bigger than the critical dimension required in the technology, then go to step S2; if said critical dimension is smaller than the critical dimension required in the technology, then go to step S4; if said critical dimension is equal to the critical dimension required in the technology, then go to step S5;
Step S2: Depositing the hard mask film to conformally cover said bottom patterned hard mask;
Step S3: Measuring the critical dimension of the hard mask of which the position is corresponding to contact holes; if said critical dimension is bigger than the critical dimension required in the technology, then return to step S2; if said critical dimension is smaller than the critical dimension required in the technology, then go to step S4; if said critical dimension is equal to the critical dimension required in the technology, then go to step S5;
Step S4: Removing the redundant hard mask by etching technology, and let the critical dimension of the contact hole be equal to the critical dimension required in the technology;
Step S5: Etching the sillicon substrate using the hard mask which has a critical dimension fitting the requirement in the technology as a mask; after forming a contact hole, removing the rest hard mask;

2. The method according to claim 1, further comprising depositing the hard mask film in step S2 by chemical deposition technology.

3. The method according to claim 2, further comprising executing the etching in step S4 by SiCoNi etching technology.

4. The method according to claim 3, further comprising etching contact holes in step S5 by dry etching technology.

5. The method according to claim 4, further comprising removing the rest hard mask in step S5 by wet etching technology.

6. The method according to claim 1, wherein the diameter of the formed contact holes ranges from least about 1 nm to most about 100 nm.

7. The method according to claim 6, wherein the depth of the formed contact holes ranges from at least about 1 nm to at most about 1000 nm.

8. A method for forming a contact hole in a substrate, the method comprising the steps of:
Step S1: preparing a first patterned hard mask corresponding to a contact hole on an upper surface of a substrate, and then measuring a critical dimension of the patterned hard mask corresponding to said contact hole; if said critical dimension is larger than a required critical dimension according to a technical specification, then go to step S2; if said critical dimension is smaller than said required critical dimension, then go to step S4; if said critical dimension is equal to said required critical dimension, then go to step S5;
Step S2: thereafter depositing a further hard mask film to conformally cover an underlying patterned hard mask, wherein said underlying patterned hard mask includes at least a portion of said first patterned hard mask;
Step S3: thereafter measuring the critical dimension of the accumulated hard mask corresponding to said contact hole; if said critical dimension of the accumulated hard mask is larger than the critical dimension according to said technical specification, then return to step S2; if said critical dimension of the accumulated hard mask is smaller than the critical dimension according to said technical specification, then go to step S4; if said critical dimension of the accumulated hard mask is equal to the critical dimension according to said technical specification, then go to step S5;
Step S4: thereafter removing excess hard mask by etching technology, so as to let the critical dimension of the contact hole be equal to the critical dimension according to said technical specification;
Step S5: thereafter etching the substrate to produce a hole substantially corresponding to said critical dimension according to said technical specification, and thereafter removing the rest of the hard mask.

9. A method of processing a semiconductor substrate comprising:
applying a mask material to said semiconductor substrate to form a first layer of mask material, said first layer of mask material having an aperture exposing a portion of said substrate, said aperture having an aperture dimension;
thereafter measuring said aperture dimension; and
thereafter performing at least one of applying additional mask material to produce an adjusted aperture with an adjusted dimension, removing previously applied mask material to produce an adjusted aperture with an adjusted dimension, and etching a resulting combination of substrate and mask material to produce a cavity in said substrate, wherein said cavity has a desirable cavity dimension.
